(19) United States
(12) Patent Application Publication
(10) Pub. No.: US 2024/0222253 A1
(43) Pub. Date: Jul. 4, 2024

(54) SEMICONDUCTOR POWER COMPONENT AND SEMICONDUCTOR POWER PACKAGE STRUCTURE

(71) Applicant: Ganstronic INC., Tainan City (TW)

(72) Inventors: Yu-Feng LIN, Tainan City (TW); Cheng-Chuan CHEN, Tainan City (TW)

(21) Appl. No.: 18/536,830

(22) Filed: Dec. 12, 2023

(30) Foreign Application Priority Data
Dec. 30, 2022 (TW) 111150828

(51) Int. Cl. H01L 23/498; H01L 23/00; H01L 23/538; H01L 25/07

(52) U.S. Cl. CPC H01L 23/49838; H01L 23/49833; H01L 23/5389; H01L 24/05; H01L 24/06; H01L 25/072; H01L 23/3121; H01L 23/49811; H01L 2224/05553; H01L 2224/0603; H01L 2224/06181

(57) ABSTRACT

A semiconductor power component includes a ceramic-metal composite substrate, a vertical transistor and a filler. The ceramic-metal composite substrate includes a ceramic insulating layer, a heat-dissipating metal layer, a bonding metal layer and a metal element. The metal element is connected to the bonding metal layer, and the bonding metal layer is located between the ceramic insulating layer and the metal element. The vertical transistor is connected to the bonding metal layer. The vertical transistor includes a conductive pad. The conductive pad is electrically connected to the bonding metal layer. The at least one metal element and the bonding metal layer are integrally formed into one.

### RELATED APPLICATIONS

This application claims priority to Taiwan application Ser. No. 11/115,0828, filed Dec. 30, 2022, which is herein incorporated by reference.

### BACKGROUND

### Technical Field

The present disclosure relates to a semiconductor power component and a semiconductor power package structure. More particularly, the present disclosure relates to a semiconductor power component and a semiconductor power package structure with enhanced manufacturing yield and reduced material cost.

### Description of Related Art

In semiconductor materials, the size of the band gap of the material is one of the important properties. The larger band gap of a semiconductor material is, the higher voltage and current the semiconductor material withstands, and the better energy conversion efficiency the semiconductor material performs. Therefore, an industry puts effort to developing high-power chips made from wide band gap (WBG) materials such as gallium nitride (GaN) or silicon carbide (SiC). The high-power chips are applied in products which require high voltage, high current, and high wattage, such as fast charging devices for electric vehicles, automotive inverters, on board chargers or high-voltage power systems.

Conventional semiconductor power package structures primarily use an upper substrate and a lower substrate to encapsulate the high-power chips, and a package structure of the high-power chips located between the upper substrate and the lower substrate is created. In order for wiring layout requirements or chips with different sizes, spacers are used during packaging to adjust the spacing. The spacers abut the high-power chips and/or the upper substrate and the lower substrate, so as to ensure the proper separation among the high-power chips, the upper substrate and the lower substrate is maintained.

However, in the manufacturing process, in order to weld the spacers to the high-power chips and/or the upper substrate and the lower substrate, one or more welding steps must be added into the packaging process. It increases the complexity of the manufacturing process and leads to a decrease in the manufacturing yield, which is unfavorable for applications in multi-chip package structures that need low fault tolerance. In addition, the high-power chips typically use wire bonding packaging for electrical connections. Thus, sufficient area of the upper substrate and the lower substrate is required to accommodate a plurality of curved bonding wires, so the upper substrate and the lower substrate must have relatively large sizes (especially the area). As a result, it is difficult to further reduce the material costs thereof. In this regard, how to improve the manufacturing yield and reduce costs in the spatial configuration of the semiconductor power package structures remains an unresolved problem.

### SUMMARY

According to one embodiment of the present disclosure, a semiconductor power component is provided. The semiconductor power component includes a ceramic-metal composite substrate, at least one vertical transistor and a filler. The ceramic-metal composite substrate includes a ceramic insulating layer, a heat-dissipating metal layer, a bonding metal layer and at least one metal element. The ceramic insulating layer has a first side and a second side opposite to the first side. The heat-dissipating metal layer is located on the first side of the ceramic insulating layer, and the bonding metal layer is located on the second side of the ceramic insulating layer. The at least one metal element is connected to the bonding metal layer, and the bonding metal layer is located between the ceramic insulating layer and the at least one metal element. The at least one vertical transistor is connected to the bonding metal layer, and the bonding metal layer is located between the ceramic insulating layer and the at least one vertical transistor. The at least one vertical transistor and the at least one metal element are separated from each other. The at least one vertical transistor has a first side and a second side opposite to the first side. The at least one vertical transistor includes a conductive pad located on the first side or the second side of the at least one vertical transistor. The conductive pad of the at least one vertical transistor is electrically connected to the bonding metal layer. The filler covers the bonding metal layer and a side of the at least one metal element and a side of the at least one vertical transistor. The at least one metal element and the bonding metal layer are integrally formed into one, and an end of the conductive pad and an end of the at least one metal element are protruding from the filler.

According to another embodiment of the present disclosure, a semiconductor power package structure is provided. The semiconductor power package structure includes at least one semiconductor power component of the aforementioned embodiment and an insulating metal circuit board. The insulating metal circuit board is connected to the at least one semiconductor power component, and the at least one vertical transistor and the at least one metal element are located between the ceramic insulating layer and the insulating metal circuit board. The insulating metal circuit board includes a ceramic layer, a plurality of first conductive metal pads and at least one heat-conductive metal pad. The ceramic layer has a first side and a second side opposite to the first side. The plurality of first conductive metal pads are located on the first side of the ceramic layer, and the plurality of first conductive metal pads are electrically connected to the conductive pad of the at least one vertical transistor. The at least one heat-conductive metal pad is located on the second side of the ceramic layer.

According to one another embodiment of the present disclosure, a semiconductor power component is provided. The semiconductor power component includes a ceramic-metal composite substrate, at least one flip chip and a filler. The ceramic-metal composite substrate includes a ceramic insulating layer, a heat-dissipating metal layer, a bonding metal layer and at least one metal element. The ceramic insulating layer has a first side and a second side opposite to the first side. The heat-dissipating metal layer is located on the first side of the ceramic insulating layer, and the bonding metal layer is located on the second side of the ceramic insulating layer. The at least one metal element is connected to the bonding metal layer, and the bonding metal layer is located between the ceramic insulating layer and the at least one metal element. The at least one flip chip is connected to the bonding metal layer, and the at least one flip chip and the at least one metal element are separated from each other. The at least one flip chip includes a heterogeneous substrate, a semiconductor structure layer and a plurality of conductive pads. The heterogeneous substrate is connected to the bonding metal layer, and the bonding metal layer is located between the ceramic insulating layer and the heterogeneous substrate. The semiconductor structure layer is disposed on the heterogeneous substrate. The plurality of conductive pads are disposed on the semiconductor structure layer and electrically connected to the semiconductor structure layer. The semiconductor structure layer is located between the heterogeneous substrate and the plurality of conductive pads. The filler covers the bonding metal layer and a side of the at least one metal element and a side of the at least one flip chip. The at least one metal element and the bonding metal layer are integrally formed into one, and an end of each of the plurality of conductive pads and an end of the at least one metal element are protruding from the filler.

According to still another embodiment of the present disclosure, a semiconductor power package structure is provided. The semiconductor power package structure includes at least one semiconductor power component of the aforementioned embodiment and an insulating metal circuit board. The insulating metal circuit board is connected to the at least one semiconductor power component, and the at least one flip chip and the at least one metal element are located between the ceramic insulating layer and the insulating metal circuit board. The insulating metal circuit board includes a ceramic layer, a plurality of first conductive metal pads and at least one heat-conductive metal pad. The ceramic layer has a first side and a second side opposite to the first side. The plurality of first conductive metal pads are located on the first side of the ceramic layer, and the plurality of first conductive metal pads are respectively electrically connected to the plurality of conductive pads. The at least one heat-conductive metal pad is located on the second side of the ceramic layer.

According to still another embodiment of the present disclosure, a semiconductor power component is provided. The semiconductor power component includes a ceramic-metal composite substrate, a vertical transistor, a flip chip and a filler. The ceramic-metal composite substrate includes a ceramic insulating layer, a heat-dissipating metal layer, two bonding metal layers and two metal elements. The ceramic insulating layer has a first side and a second side opposite to the first side. The heat-dissipating metal layer is located on the first side of the ceramic insulating layer, and the two bonding metal layers are respectively located on the second side of the ceramic insulating layer. The two metal elements are respectively connected to the two bonding metal layers, and each of the two bonding metal layers is located between the ceramic insulating layer and the corresponding metal element. The vertical transistor is connected to one of the two bonding metal layers, and the one of the two bonding metal layers is located between the ceramic insulating layer and the vertical transistor. The vertical transistor and the metal element connected to the one of the two bonding metal layers are separated from each other. The vertical transistor has a first side and a second side opposite to the first side. The vertical transistor includes a conductive pad, and the conductive pad is disposed on the first side or the second side of the vertical transistor. The conductive pad of the vertical transistor is electrically connected to the one of the two bonding metal layers. The flip chip is connected to the other one of the two bonding metal layers, and is separated from the metal element connected to the other one of the two bonding metal layers. The flip chip includes a heterogeneous substrate, a semiconductor structure layer and a plurality of conductive pads. The heterogeneous substrate is connected to the other one of the two bonding metal layers, and the other one of the two bonding metal layers is located between the ceramic insulating layer and the heterogeneous substrate. The semiconductor structure layer is located on the heterogeneous substrate. The plurality of conductive pads are located on the semiconductor structure layer and are electrically connected to the semiconductor structure layer. The semiconductor structure layer is located between the heterogeneous substrate and the plurality of conductive pads. The filler covers the two bonding metal layers and sides of the two metal elements, a side of the vertical transistor and a side of the flip chip. Each of the two metal elements and the corresponding bonding metal layer are integrally formed into one, and an end of the conductive pad of the vertical transistor, an end of each of the plurality of conductive pads of the flip chip and an end of each of the two metal elements are protruding from the filler.

According to still another embodiment of the present disclosure, a semiconductor power package structure is provided. The semiconductor power package structure includes the semiconductor power component of the aforementioned embodiment and an insulating metal circuit board. The insulating metal circuit board is connected to the semiconductor power component, and the vertical transistor, the flip chip, and the two metal elements are located between the ceramic insulating layer and the insulating metal circuit board. The insulating metal circuit board includes a ceramic layer, a plurality of first conductive metal pads and at least one heat-conductive metal pad. The ceramic layer has a first side and a second side opposite to the first side. The plurality of first conductive metal pads are located on the first side of the ceramic layer, and the plurality of first conductive metal pads are respectively electrically connected to the conductive pad of the vertical transistor and the plurality of conductive pads of the flip chip. The at least one heat-conductive metal pad is located on the second side of the ceramic layer.

### BRIEF DESCRIPTION OF THE DRAWINGS

The present disclosure can be more fully understood by reading the following detailed description of the embodiment, with reference made to the accompanying drawings as follows:

FIG. 1 is a cross-sectional schematic view of the semiconductor power component according to the 1st embodiment of the present disclosure.

FIG. 2A is a top schematic view of the semiconductor power component of FIG. 1.

FIG. 2B is a bottom schematic view of the semiconductor power component of FIG. 1.

FIG. 3 is a cross-sectional schematic view of the semiconductor power component according to the 2nd embodiment of the present disclosure.

FIG. 4 is a bottom schematic view of the semiconductor power component of FIG. 3.

FIG. 5 is a cross-sectional schematic view of the semiconductor power component according to the 3rd embodiment of the present disclosure.

FIG. 6 is a bottom schematic view of the semiconductor power component of FIG. 5.

FIG. 7 is a cross-sectional schematic view of the semiconductor power component according to the 4th embodiment of the present disclosure.

FIG. 8 is a bottom schematic view of the semiconductor power component of FIG. 7.

FIG. 9 is a cross-sectional schematic view of the semiconductor power component according to the 5th embodiment of the present disclosure.

FIG. 10 is a cross-sectional schematic view of the semiconductor power component according to the 6th embodiment of the present disclosure.

FIG. 11 is a bottom schematic view of the semiconductor power component of FIG. 10.

FIG. 12 is a cross-sectional schematic view of the semiconductor power package structure according to the 7th embodiment of the present disclosure.

FIG. 13A is a top schematic view of the semiconductor power package structure of FIG. 12.

FIG. 13B is a top schematic view of the insulating metal circuit board of FIG. 12.

FIG. 13C is a bottom schematic view of the insulating metal circuit board of FIG. 12.

FIG. 14 is a cross-sectional schematic view of the semiconductor power package structure according to the 8th embodiment of the present disclosure.

FIG. 15A is a top schematic view of the insulating metal circuit board of FIG. 14.

FIG. 15B is a bottom schematic view of the insulating metal circuit board of FIG. 14.

FIG. 16 is a cross-sectional schematic view of the semiconductor power package structure according to the 9th embodiment of the present disclosure.

FIG. 17 is a cross-sectional schematic view of the semiconductor power package structure according to the 10th embodiment of the present disclosure.

FIG. 18A is a top schematic view of the semiconductor power package structure of FIG. 17.

FIG. 18B is a top schematic view of the insulating metal circuit board of FIG. 17.

FIG. 18C is a bottom schematic view of the insulating metal circuit board of FIG. 17.

FIG. 19 is a cross-sectional schematic view of the semiconductor power package structure according to the 11th embodiment of the present disclosure.

FIG. 20 is a cross-sectional schematic view of the semiconductor power package structure according to the 12th embodiment of the present disclosure.

FIG. 21 is a cross-sectional schematic view of the semiconductor power package structure according to the 13th embodiment of the present disclosure.

FIG. 22 is a cross-sectional schematic view of the semiconductor power package structure according to the 14th embodiment of the present disclosure.

### DETAILED DESCRIPTION

The present disclosure will be further exemplified by the following specific embodiments. However, the embodiments can be applied to various inventive concepts and can be embodied in various specific ranges. The specific embodiments are only for the purposes of description, and are not limited to these practical details thereof.

Furthermore, in order to simplify the drawings, some conventional structures and elements will be illustrated in the drawings by a simple and schematic way. The duplicated elements may be denoted by the same number or similar numbers. If not specifically stated, the aforementioned duplicated elements may have the same structural features in different embodiments or examples. If the differences of a single element between different embodiments or examples are explained or shown, it should be considered according to the explanations or the figures.

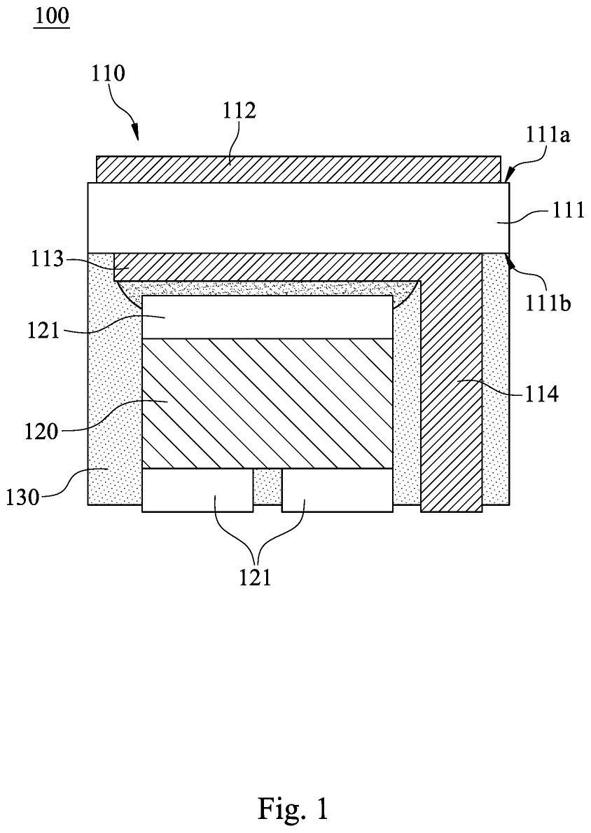

Please refer to FIG. 1. FIG. 1 is a cross-sectional schematic view of the semiconductor power component 100 according to the 1st embodiment of the present disclosure. The semiconductor power component 100 includes a ceramic-metal composite substrate 110, at least one vertical transistor 120 and a filler 130. The vertical transistor 120 is connected to the ceramic-metal composite substrate 110, and the filler 130 covers at least a portion of the ceramic-metal composite substrate 110 and the vertical transistor 120.

In detail, the ceramic-metal composite substrate 110 includes a ceramic insulating layer 111, a heat-dissipating metal layer 112, a bonding metal layer 113 and at least one metal element 114. The ceramic insulating layer 111 has a first side 111a and a second side 111b opposite to the first side 111a. The heat-dissipating metal layer 112 is located on the first side 111a of the ceramic insulating layer 111, and the bonding metal layer 113 is located on the second side 111b of the ceramic insulating layer 111. The metal element 114 is connected to the bonding metal layer 113, and the bonding metal layer 113 is located between the ceramic insulating layer 111 and the metal element 114.

The vertical transistor 120 is connected to the bonding metal layer 113, where the bonding metal layer 113 is located between the ceramic insulating layer 111 and the vertical transistor 120. The vertical transistor 120 and the metal element 114 are separated from each other, and the vertical transistor 120 is electrically connected to the bonding metal layer 113. In detail, the vertical transistor 120 has a first side (its number is omitted) and a second side (its number is omitted) opposite to the first side. The vertical transistor 120 includes a plurality of conductive pads 121, and the plurality of conductive pads 121 are respectively disposed on the first side or the second side of the vertical transistor 120. The plurality of conductive pads 121 on the first side of the vertical transistor 120 are electrically connected to the bonding metal layer 113. The plurality of conductive pads 121 can be a drain, a gate and a source. In the present embodiment, the drain is located on the first side of the vertical transistor 120, and the gate and the source are located on the second side of the vertical transistor 120. In other embodiments, the gate and the source can be located on the first side of the vertical transistor and electrically connected to the bonding metal layer, while the drain can be located on the second side of the vertical transistor. Alternatively, other configurations are also possible, so the positions of the drain, the gate and the source are not limited in the present disclosure.

When the vertical transistor 120 is connected to the bonding metal layer 113, both heat and current can be transferred to the bonding metal layer 113.

The current can pass through the bonding metal layer 113 and the metal element 114 to the outside. Besides transferred through the path for current, heat can be further transferred to the ceramic insulating layer 111 and discharged through the heat-dissipating metal layer 112, so the heat dissipation can be improved. Furthermore, as the current can be transmitted to the outside through the metal element 114, there is no need for additional wire bonding in the semiconductor power component 100. Therefore, the overall size of the semiconductor power component 100 can be effectively reduced, and the manufacturing yield can be enhanced.

The metal element 114 and the bonding metal layer 113 of the semiconductor power component 100 are integrally formed into one. For example, the metal element 114 can be formed on the bonding metal layer 113 by a physical vapor deposition method or an electroplating method. The materials for the bonding metal layer 113 and the metal element 114 can be copper metal, and the height of the metal element 114 can be flexibly adjusted for the vertical transistor 120 with different sizes. By the integral formation, there is no need for additional welding of the bonding metal layer 113 and the metal element 114 during packaging, so the packaging steps can be reduced and the manufacturing yield can be improved. Also, the present embodiment is more favorable for reducing the size of the ceramic-metal composite substrate 110 compared to conventional wire bonding packaging.

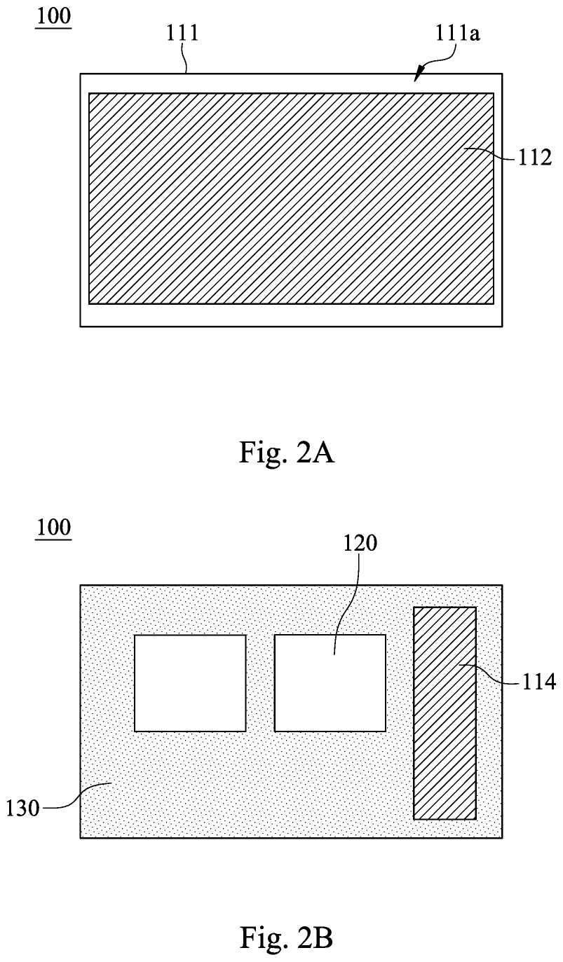

Please also refer to FIG. 2A and FIG. 2B. FIG. 2A is a top schematic view of the semiconductor power component 100 of FIG. 1. FIG. 2B is a bottom schematic view of the semiconductor power component 100 of FIG. 1. In FIG. 2A, the heat-dissipating metal layer 112 can be extensively disposed on the first side 111a of the ceramic insulating layer 111 to increase the heat dissipation efficiency. Furthermore, in FIG. 2B, the metal element 114 is located on one side of the vertical transistor 120, and the bottom surface of the metal element 114 is rectangular. Thus, the good support, electrical conduction and heat conduction can be provided by the metal element 114.

The filler 130 covers the bonding metal layer 113, a side of the metal element 114 and a side of the vertical transistor 120, so as to protect the bonding metal layer 113, the metal element 114 and the vertical transistor 120. The filler 130 can be made of a material including a polymer and a thermally conductive powder. The thermally conductive powder can be selected from the group consisting of carbon, aluminum nitride, boron nitride, silicon carbide, aluminum oxide, zinc oxide and graphene. By using the aforementioned materials, the filler 130 can assist in transfer the heat of the vertical transistor 120, and the heat dissipation can be further enhanced.

Furthermore, in the practical manufacturing process, the filler 130 can first cover the metal element 114 and the vertical transistor 120. Then, the filler 130 can be ground to make an end of each of the plurality of conductive pads 121 of the vertical transistor 120 and an end of the metal element 114 be protruding from the filler 130 for the further assembly and connection.

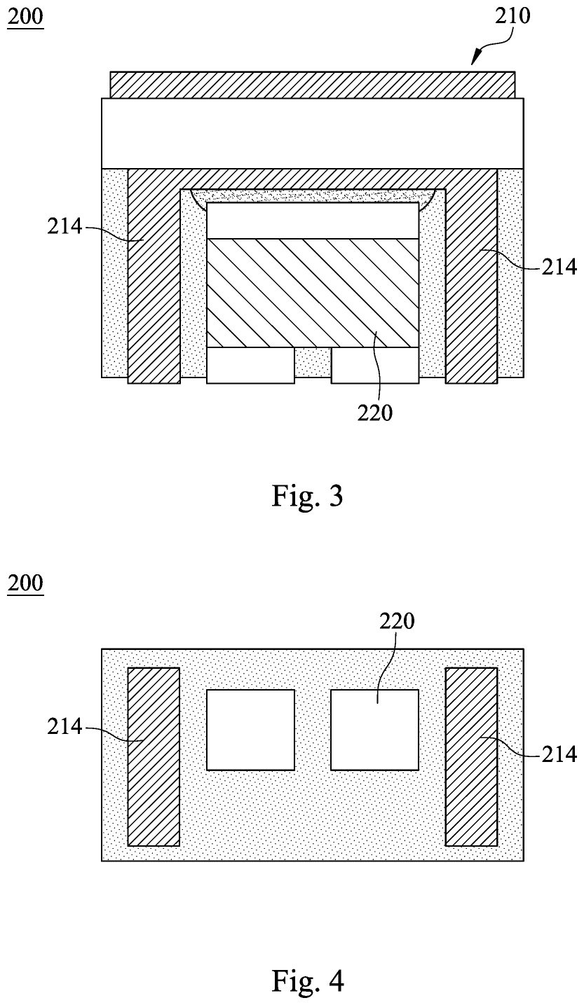

Please refer to FIG. 3 and FIG. 4. FIG. 3 is a cross-sectional schematic view of the semiconductor power component 200 according to the 2nd embodiment of the present disclosure. FIG. 4 is a bottom schematic view of the semiconductor power component 200 of FIG. 3. The semiconductor power component 200 of the 2nd embodiment is generally similar to the semiconductor power component 100 of the 1st embodiment. The difference is that, in the semiconductor power component 200, the number of the metal elements 214 is two, and the vertical transistor 220 is located between the two metal elements 214. In FIG. 3, a more stable support for the ceramic-metal composite substrate 210 can be provided by the two metal elements 214.

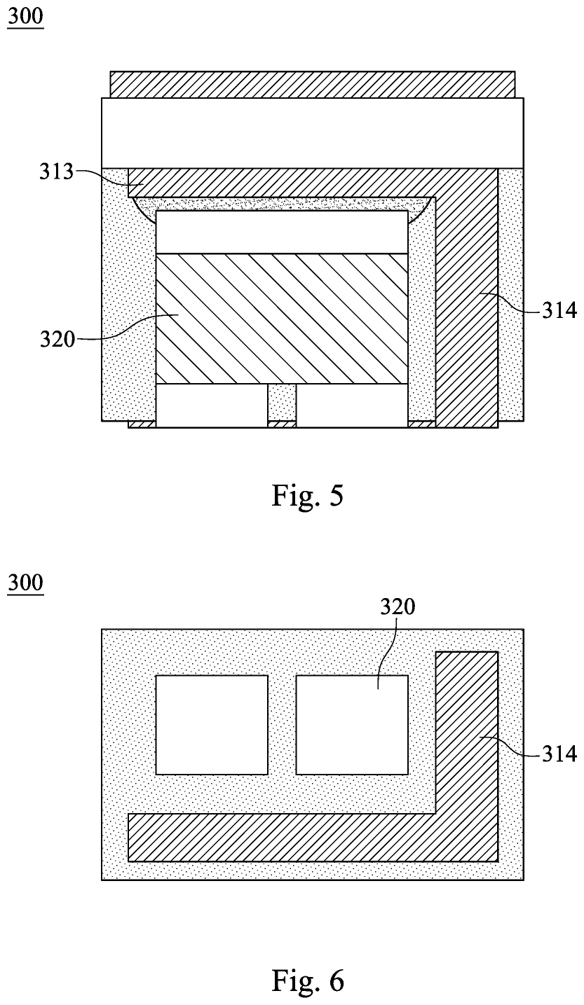

Please refer to FIG. 5 and FIG. 6. FIG. 5 is a cross-sectional schematic view of the semiconductor power component 300 according to the 3rd embodiment of the present disclosure. FIG. 6 is a bottom schematic view of the semiconductor power component 300 of FIG. 5. The semiconductor power component 300 of the 3rd embodiment is generally similar to the semiconductor power component 100 of the 1st embodiment. For example, the bonding metal layer 313 and the metal element 314 are integrally formed into one. The metal element 314 can be formed on the bonding metal layer 313 through the physical vapor deposition method or the electroplating method.

The difference between the semiconductor power component 300 and the semiconductor power component 100 is that, in the semiconductor power component 300, the metal element 314 partially surrounds the vertical transistor 320 in the horizontal direction. A connecting area between the metal element 314 and the bonding metal layer 313 becomes L shape, and the aforementioned L-shaped connecting area equals to the overlapping region between the metal element 314 and the bonding metal layer 313. Therefore, the volume of the metal element 314 increases, so the support is improved and it is favorable for transferring the heat from the vertical transistor 320.

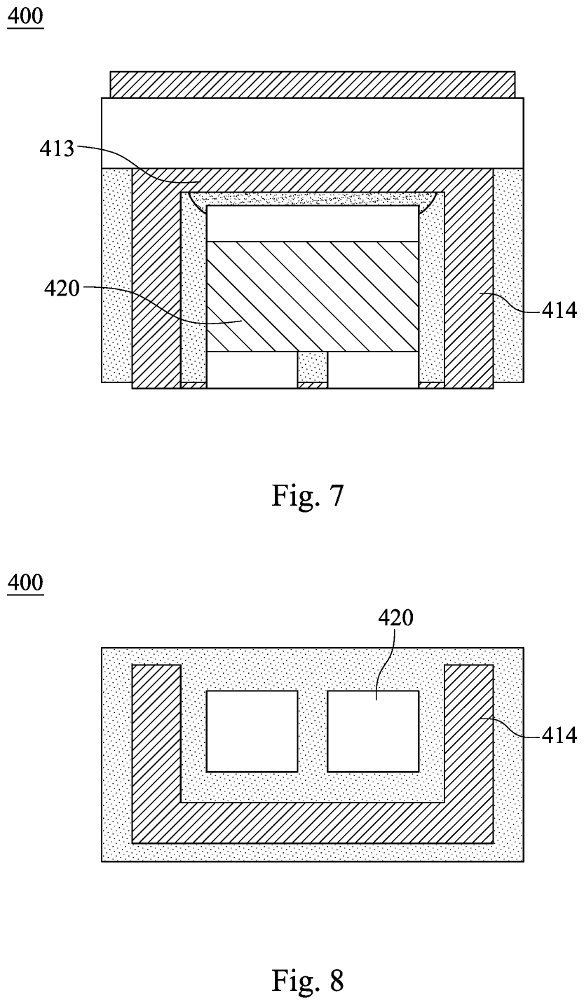

Please refer to FIG. 7 and FIG. 8. FIG. 7 is a cross-sectional schematic view of the semiconductor power component 400 according to the 4th embodiment of the present disclosure. FIG. 8 is a bottom schematic view of the semiconductor power component 400 of FIG. 7. The semiconductor power component 400 of the 4th embodiment is generally similar to the semiconductor power component 100 of the 1st embodiment. The difference is that, in the semiconductor power component 400, the metal element 414 partially surrounds the vertical transistor 420 in the horizontal direction. A connecting area between the metal element 414 and the bonding metal layer 413 becomes U shape, and the aforementioned U-shaped connecting area equals to the overlapping region between the metal element 414 and the bonding metal layer 413. Therefore, the volume of the metal element 414 increases, so the support is improved and it is favorable for transferring the heat from the vertical transistor 420.

Moreover, in other embodiments, the metal elements can be in different positions or have different shapes, as long as an enough space is reserved for filling the filler to cover the chips therein. Therefore, it should be mentioned that the numbers and shapes of the metal element 114, the metal elements 214, the metal element 314 or the metal element 414 are not limited in the present disclosure.

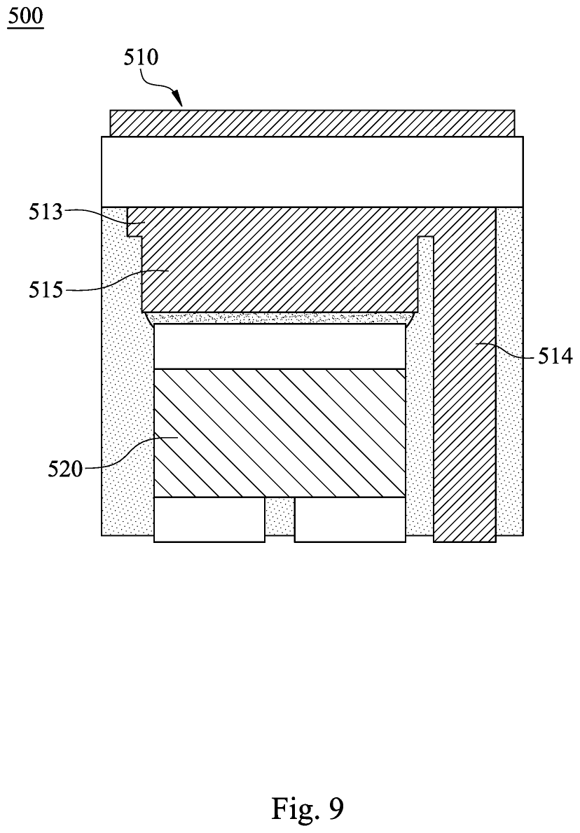

Please refer to FIG. 9. FIG. 9 is a cross-sectional schematic view of the semiconductor power component 500 according to the 5th embodiment of the present disclosure. The semiconductor power component 500 of the 5th embodiment is generally similar to the semiconductor power component 100 of the 1st embodiment. The difference is that, in the semiconductor power component 500, the ceramic-metal composite substrate 510 further includes a die-bonding platform 515. The die-bonding platform 515 is connected to the bonding metal layer 513. The vertical transistor 520 is disposed on the die-bonding platform 515 and electrically connected to the die-bonding platform 515. The die-bonding platform 515 can be located between the bonding metal layer 513 and the vertical transistor 520.

In the practical manufacturing process, the vertical transistor 520 can have different sizes to meet the different requirements. Therefore, by arranging the die-bonding platform 515 and by adjusting the height of the die-bonding platform 515 and the height of the metal element 514, the ceramic-metal composite substrate 510 can be adapted to the vertical transistor 520 of various sizes, so the application range of the semiconductor power component 500 can be expanded.

Furthermore, the die-bonding platform 515 and the bonding metal layer 513 can be integrally formed into one. For example, the die-bonding platform 515 can be formed on the bonding metal layer 513 through the physical vapor deposition method or the electroplating method. The materials for the bonding metal layer 513 and the die-bonding platform 515 can be copper metal. By the integral formation, there is no need for additional welding of the bonding metal layer 513 and the die-bonding platform 515 during packaging, so the packaging steps can be reduced and the manufacturing yield can be improved.

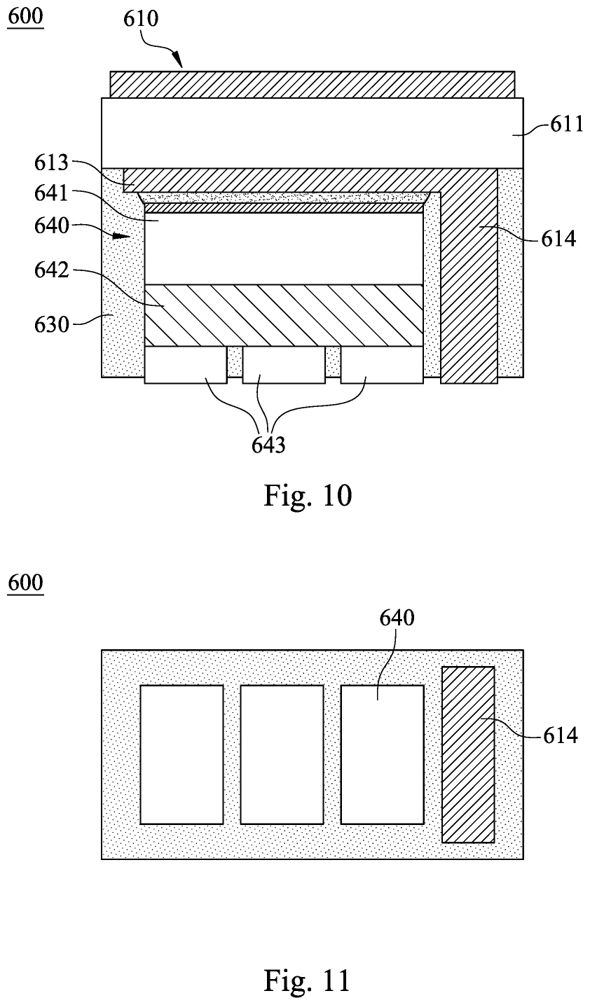

Please refer to FIG. 10. FIG. 10 is a cross-sectional schematic view of the semiconductor power component 600 according to the 6th embodiment of the present disclosure. The semiconductor power component 600 includes a ceramic-metal composite substrate 610, at least one flip chip 640 and a filler 630. The flip chip 640 is connected to the ceramic-metal composite substrate 610, and the filler 630 covers at least a portion of the ceramic-metal composite substrate 610 and the flip chip 640. The structures and the materials of the ceramic-metal composite substrate 610 and the filler 630 are the same as the ceramic-metal composite substrate 110 and the filler 130 of the 1st embodiment in the foregoing description. The filler 630 covers a side of the flip chip 640 in the same way as the filler 130 covers the side of the vertical transistor 120 in the 1st embodiment, so the detailed explanation thereof will not be given again herein.

The flip chip 640 is connected to the bonding metal layer 613 and is separated from the metal element 614. The flip chip 640 includes a heterogeneous substrate 641, a semiconductor structure layer 642 and a plurality of conductive pads 643. The heterogeneous substrate 641 is connected to the bonding metal layer 613, and the bonding metal layer 613 is located between the ceramic insulating layer 611 and the heterogeneous substrate 641. The semiconductor structure layer 642 is disposed on the heterogeneous substrate 641. The plurality of conductive pads 643 are disposed on the semiconductor structure layer 642 and electrically connected to the semiconductor structure layer 642. The semiconductor structure layer 642 is located between the heterogeneous substrate 641 and the plurality of conductive pads 643.

The heterogeneous substrate 641 of the flip chip 640 can be a native substrate or a non-native substrate. The native substrate can be an insulating substrate or a non-conductive substrate, and the non-native substrate can be a non-conductive substrate or a non-insulating substrate. When the heterogeneous substrate 641 is the insulating substrate, the heterogeneous substrate 641 can be a sapphire substrate, a silicon insulating substrate, a silicon-silicon oxide composite insulating substrate, a silicon-gallium nitride composite insulating substrate or a substrate made from other insulating materials. In these cases, the bonding metal layer 613 and the metal element 614 can be used for transferring the heat from the flip chip 640. Alternatively, the heterogeneous substrate 641 can be the non-conductive substrate, such as a silicon semiconductor substrate or a silicon carbide semiconductor substrate, or the heterogeneous substrate 641 can be the non-insulating substrate, such as a molybdenum substrate, a tungsten substrate, a molybdenum-copper alloy substrate or a tungsten-copper alloy substrate. In these cases, the bonding metal layer 613 and the metal element 614 can be used not only for helping the heat dissipation of the flip chip 640, but also for a ground connection.

Please also refer to FIG. 11. FIG. 11 is a bottom schematic view of the semiconductor power component 600 of FIG. 10. In FIG. 11, the metal element 614 is located on one side of the flip chip 640, and a bottom surface of the metal element 614 can be a rectangular shape. In other embodiments, the number of metal elements can be two, and the flip chip can be located between the two metal elements. Alternatively, the metal element can also partially surround the flip chip in the horizontal direction. A connecting area between the metal element and the bonding metal layer becomes L shape or U shape, and the aforementioned connecting area equals to the overlapping region between the metal element and the bonding metal layer. Furthermore, the ceramic-metal composite substrate can further include a die-bonding platform for the flip chip to be disposed thereon. The aforementioned embodiments are the same as the 2nd embodiment to the 5th embodiment in the foregoing description. The person skilled in the art can replace the vertical transistor with the flip chip or vice versa according to the requirements, and the detailed explanation thereof will not be given again in the present disclosure.

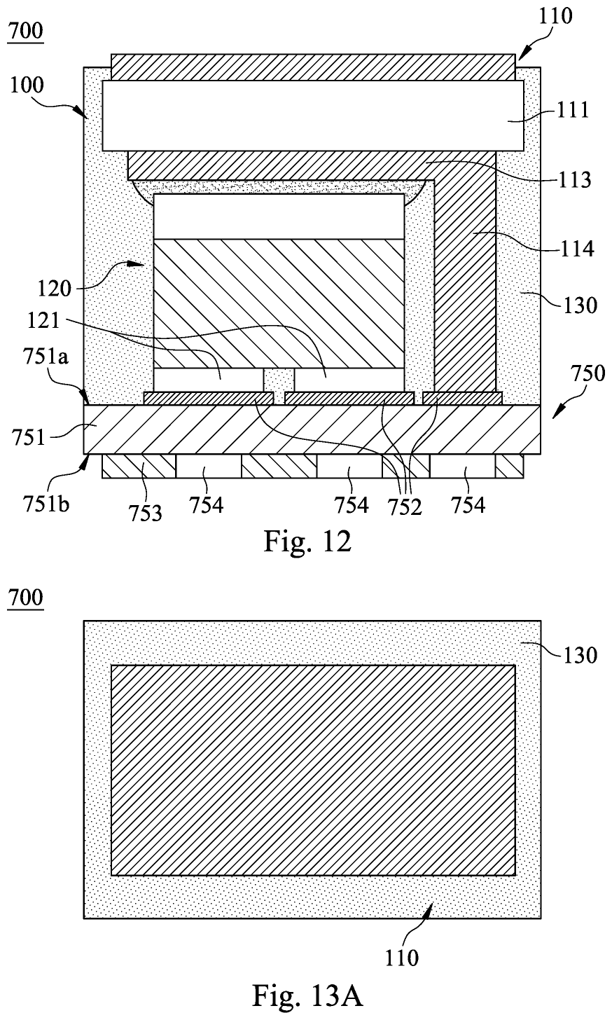

Please refer to FIG. 12. FIG. 12 is a cross-sectional schematic view of the semiconductor power package structure 700 according to the 7th embodiment of the present disclosure. The semiconductor power package structure 700 includes the semiconductor power component 100 of the 1st embodiment and an insulating metal circuit board 750, and the insulating metal circuit board 750 is connected to the semiconductor power component 100. The insulating metal circuit board 750 can be made from ceramics.

In detail, the vertical transistor 120 and the metal element 114 are located between the ceramic insulating layer 111 and the insulating metal circuit board 750. There can be a gap between the filler 130 and the insulating metal circuit board 750, and an additional filler (its number is omitted) can be disposed between the filler 130 and the insulating metal circuit board 750 to make the vertical transistor 120 and the metal element 114 be fully surrounded. The insulating metal circuit board 750 includes a ceramic layer 751, a plurality of first conductive metal pads 752 and at least one heat-conductive metal pad 753. The ceramic layer 751 has a first side 751a and a second side 751b opposite to the first side 751a. The first conductive metal pads 752 are disposed on the first side 751a of the ceramic layer 751, and the first conductive metal pads 752 are respectively electrically connected to the conductive pads 121 on the second side of the vertical transistor 120. The heat-conductive metal pad 753 is disposed on the second side 751b of the ceramic layer 751.

The metal element 114 can support the ceramic-metal composite substrate 110 and ensure that there is sufficient space between the ceramic-metal composite substrate 110 and the insulating metal circuit board 750. The current of the vertical transistor 120 can be transmitted to the insulating metal circuit board 750 through the first conductive metal pads 752 and the metal element 114, and an electrical connection to the outside can be achieved.

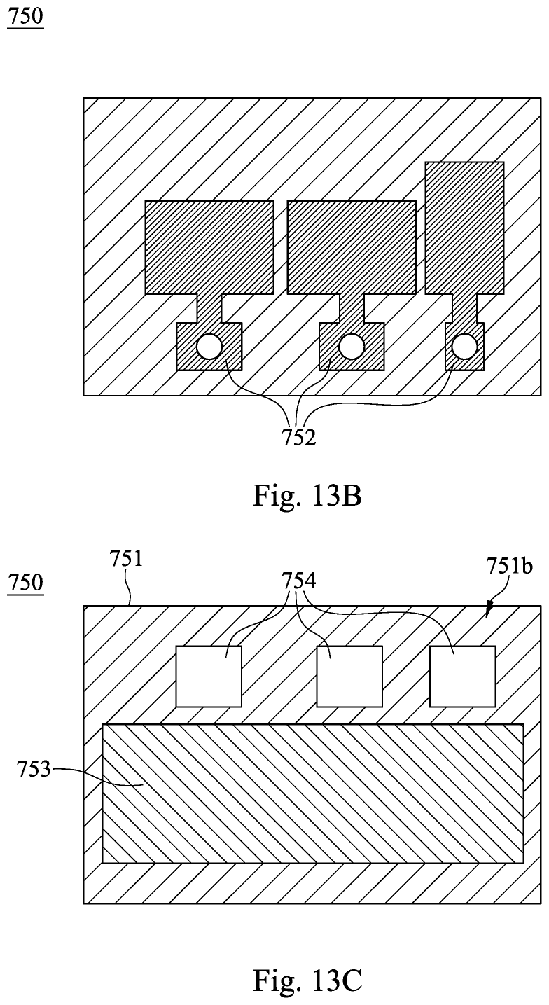

Please also refer to FIG. 13A. FIG. 13A is a top schematic view of the semiconductor power package structure 700 of FIG. 12. In FIG. 13A, because the metal element 114 and the bonding metal layer 113 are integrally formed into one, and the metal element 114 can be formed by the physical vapor deposition method or the electroplating method. Therefore, the area occupied by the metal element 114 on the ceramic-metal composite substrate 110 can be controlled, and the area of the ceramic-metal composite substrate 110 can be significantly reduced. In this regard, it does not need to perform a wire-bonding package on the semiconductor power component 100, and the size of the semiconductor power component 100 can be reduced.

Please also refer to FIG. 12, FIG. 13B, and FIG. 13C. FIG. 13B is a top schematic view of the insulating metal circuit board 750 of FIG. 12. FIG. 13C is a bottom schematic view of the insulating metal circuit board 750 of FIG. 12. The insulating metal circuit board 750 can further include a plurality of second conductive metal pads 754. The second conductive metal pads 754 are located on the second side 751b of the ceramic layer 751, and the second conductive metal pads 754 are respectively electrically connected to the first conductive metal pads 752. Therefore, the current of the vertical transistor 120 can be transferred from the second side 751b of the ceramic layer 751, and the subsequent circuit configuration can be more flexible. Moreover, although the heat-conductive metal pad 753 are also located on the second side 751b of the ceramic layer 751, the heat-conductive metal pad 753 are not electrically connected to the first conductive metal pads 752 and the second conductive metal pads 754, and not involved in the electrical functions of the vertical transistor 120.

In the present embodiment, a single semiconductor power component 100 is taken as an example. However, in other embodiments, a plurality of semiconductor power components can be included, and each of the semiconductor power components can be any one of the semiconductor power components described in the aforementioned embodiments. It should be mentioned that, the semiconductor power components are not limited to the disclosure of the 1st embodiment, and not limited to the same embodiment.

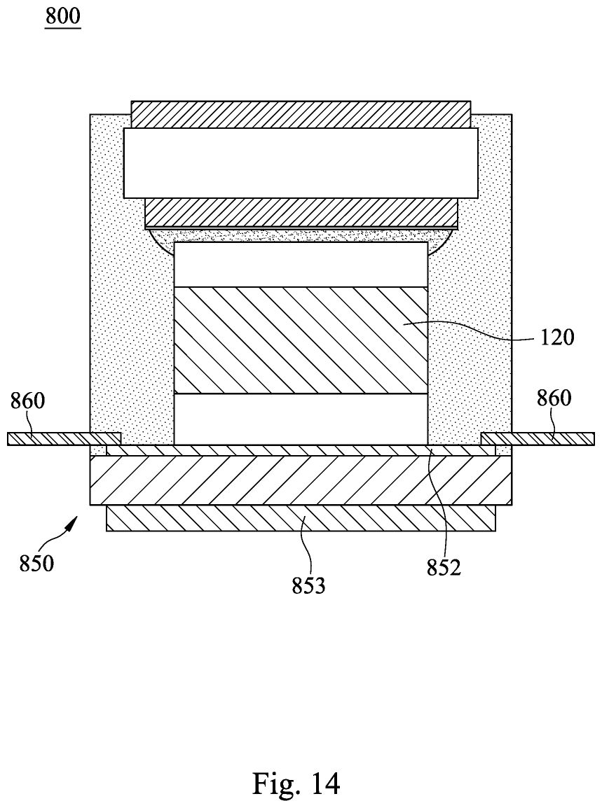

Please refer to FIG. 14. FIG. 14 is a cross-sectional schematic view of the semiconductor power package structure 800 according to the 8th embodiment of the present disclosure. The semiconductor power package structure 800 of the 8th embodiment is generally similar to the semiconductor power package structure 700 of the 7th embodiment. The difference is that, the insulating metal circuit board 850 of the semiconductor power package structure 800 does not have the second conductive metal pad. Therefore, the semiconductor power package structure 800 further includes a plurality of metal conductors 860, and the metal conductors 860 are electrically connected to the first conductive metal pads 852. Thus, the current of the vertical transistor 120 can be transmitted to external components through the metal conductors 860.

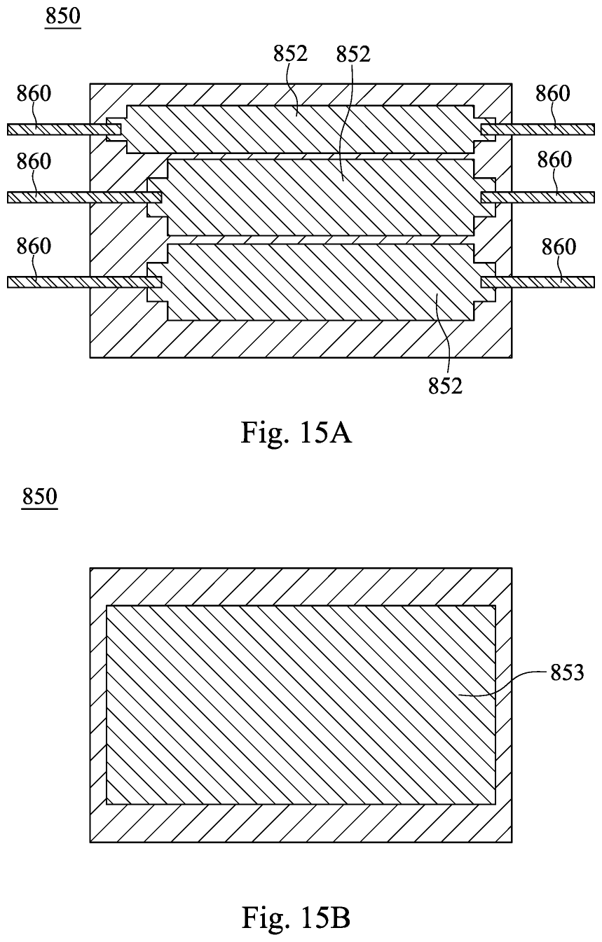

Please also refer to FIG. 15A and FIG. 15B. FIG. 15A is a top schematic view of the insulating metal circuit board 850 of FIG. 14. FIG. 15B is a bottom schematic view of the insulating metal circuit board 850 of FIG. 14. In FIG. 15A, one end of each the metal conductors 860 is connected to the first conductive metal pads 852, and the other end thereof extends out of the insulating metal circuit board 850 for the connection to other components. The metal conductors 860 can have different shapes or configurations according to the requirements, so the present disclosure is not limited thereto. In FIG. 15B, because the insulating metal circuit board 850 does not have the second conductive metal pad, the arranged area of the heat-conductive metal pad 853 can be increased, and the heat dissipation efficiency can be improved.

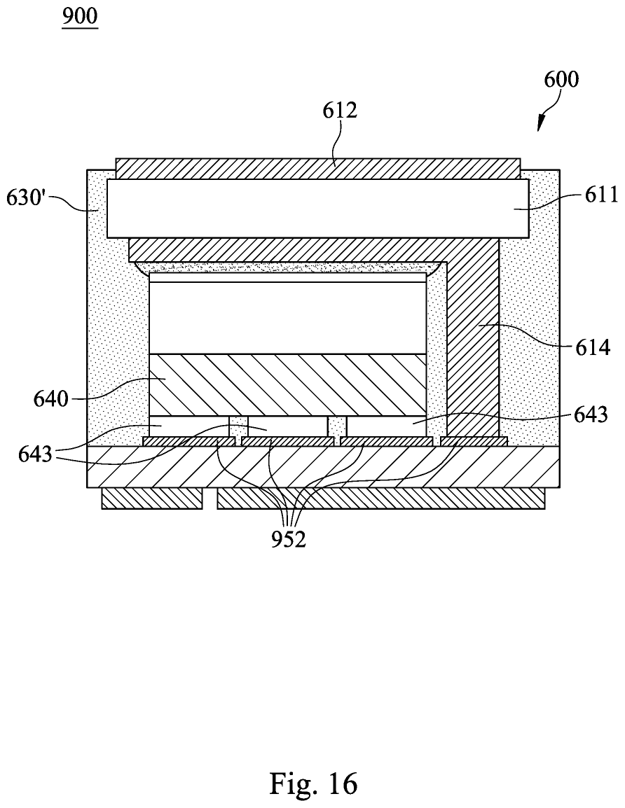

Please refer to FIG. 16. FIG. 16 is a cross-sectional schematic view of the semiconductor power package structure 900 according to the 9th embodiment of the present disclosure. The semiconductor power package structure 900 of the 9th embodiment is generally similar to the semiconductor power package structure 700 of the 7th embodiment. The difference is that, the semiconductor power package structure 900 includes the semiconductor power component 600 of the 6th embodiment instead of that of the 1st embodiment. Therefore, the flip chip 640 of the semiconductor power component 600 is electrically connected to the first conductive metal pads 952 through the conductive pads 643, and the metal element 614 can be used for heat dissipation and/or grounding.

Furthermore, in the present embodiment, the filler 630′ covers the ceramic insulating layer 611 and covers at least a portion of a side of the heat-dissipating metal layer 612, but does not cover a surface of the heat-dissipating metal layer 612 away from the ceramic insulating layer 611. Thus, the structure of the heat-dissipating metal layer 612 embedded in the filler 630′ can be formed, and the heat-dissipating metal layer 612 can be further protected and it ensures that the heat dissipation effect of the heat-dissipating metal layer 612 is not affected by the filler 630′. The structure of the filler 630′ in the present embodiment can also be freely applied to the semiconductor power components and the semiconductor power package structures of other embodiments, and the present embodiment is not limited to the aforementioned structure.

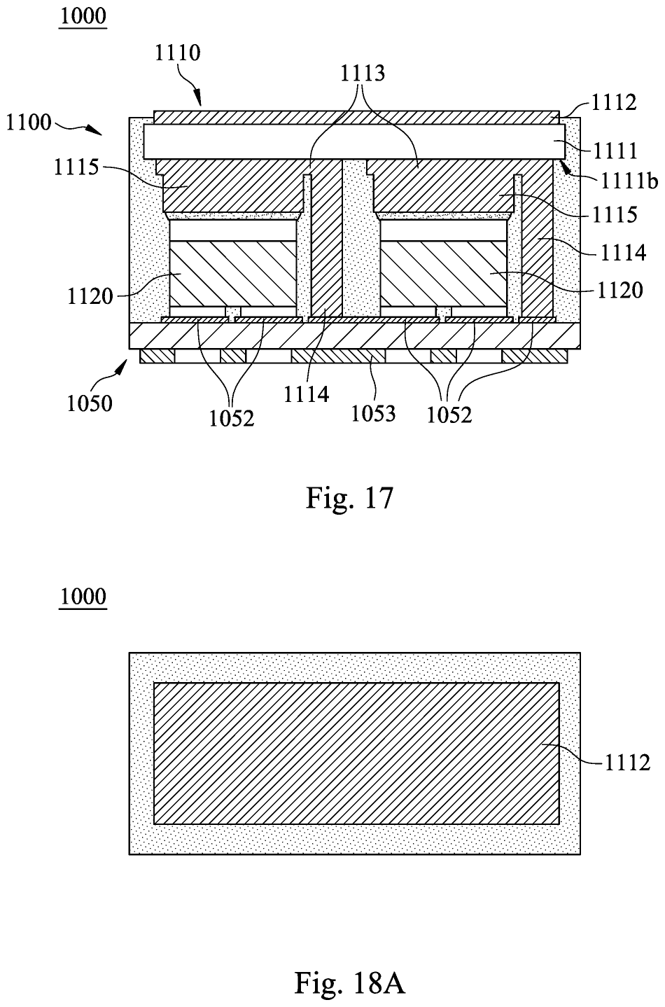

Please refer to FIG. 17. FIG. 17 is a cross-sectional schematic view of the semiconductor power package structure 1000 according to the 10th embodiment of the present disclosure. The semiconductor power package structure 1000 of the 10th embodiment is generally similar to the semiconductor power package structure 700 of the 7th embodiment. The difference is that, the semiconductor power component 1100 of the semiconductor power package structure 1000 includes two bonding metal layers 1113, two die-bonding platforms 1115, two metal elements 1114 and two vertical transistors 1120.

In detail, the aforementioned two bonding metal layers 1113 are respectively disposed on the second side 1111b of the ceramic insulating layer 1111. The two die-bonding platforms 1115 are respectively connected to the two bonding metal layers 1113. The two metal elements 1114 are respectively connected to the two bonding metal layers 1113, and the two vertical transistors 1120 are respectively disposed on the two die-bonding platforms 1115 and electrically connected to the corresponding die-bonding platforms 1115. The arrangement of the bonding metal layers 1113, the die-bonding platforms 1115, the metal elements 1114 and the vertical transistors 1120 is similar to the aforementioned 5th embodiment, so the detailed explanation thereof will not be given again herein.

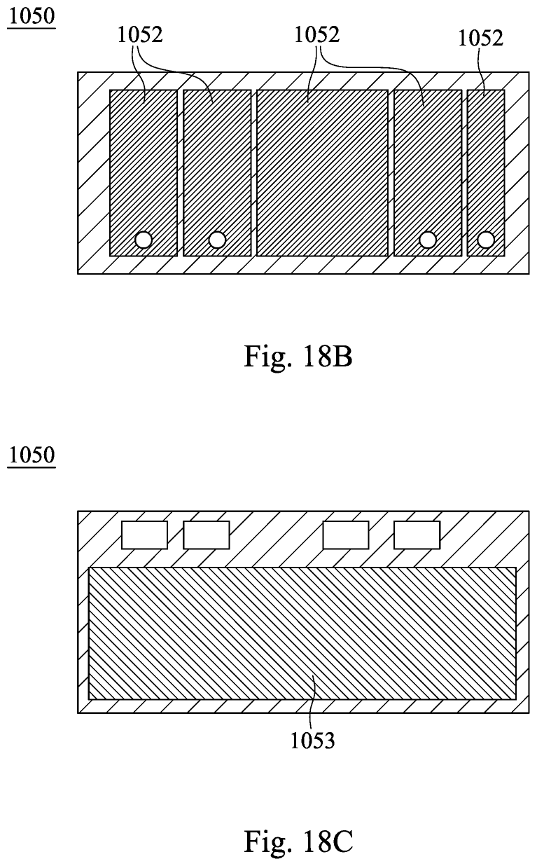

Please also refer to FIG. 18A. FIG. 18A is a top schematic view of the semiconductor power package structure 1000 of FIG. 17. In FIG. 18A, because the aforementioned two vertical transistors 1120 are jointly installed on the ceramic-metal composite substrate 1110, the area of the ceramic-metal composite substrate 1110 should be moderately enlarged, so the area of the heat-dissipating metal layer 1112 can be enlarged at the same time and the heat dissipation efficiency can be enhanced. However, it should be mentioned that, although the area of the ceramic-metal composite substrate 1110 is increased in the present disclosure, the metal elements 1114 and the die-bonding platforms 1115 are still integrally formed with the bonding metal layers 1113 and perform the circuit functions. Therefore, it is still effective in reducing the area of the ceramic-metal composite substrate 1110 in the present embodiment as compared to the conventional package structure with two chips.

Please also refer to FIG. 18B and FIG. 18C. FIG. 18B is a top schematic view of the insulating metal circuit board 1050 of FIG. 17. FIG. 18C is a bottom schematic view of the insulating metal circuit board 1050 of FIG. 17. The insulating metal circuit board 1050 includes five first conductive metal pads 1052 for electrical connection to the semiconductor power component 1100. Each of the vertical transistors 1120 is electrically connected to three of the first conductive metal pads 1052, and one of the first conductive metal pads 1052 is electrically connected to the aforementioned two vertical transistors 1120 simultaneously. Therefore, the two vertical transistors 1120 can be directly interconnected through the first conductive metal pads 1052 for electrical connection. However, the actual connection thereof can be adjusted according to the requirements, and the present disclosure is not limited thereto.

Furthermore, in FIG. 18C, the area of the insulating metal circuit board 1050 is also increased to match the size of the semiconductor power component 1100. Therefore, the area of the heat-conductive metal pad 1053 can increase, so the heat dissipation efficiency can be improved.

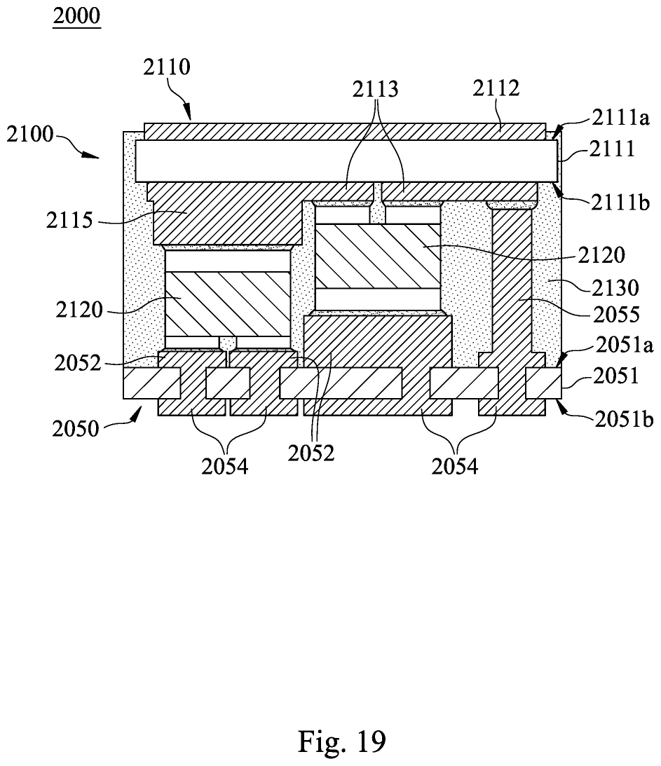

Please refer to FIG. 19. FIG. 19 is a cross-sectional schematic view of the semiconductor power package structure 2000 according to the 11th embodiment of the present disclosure. The semiconductor power package structure 2000 includes the semiconductor power component 2100 and an insulating metal circuit board 2050, and the insulating metal circuit board 2050 is connected to the semiconductor power component 2100.

In detail, the semiconductor power component 2100 includes a ceramic-metal composite substrate 2110, two vertical transistors 2120 and a filler 2130. The ceramic-metal composite substrate 2110 includes a ceramic insulating layer 2111, a heat-dissipating metal layer 2112, two bonding metal layers 2113 and a die-bonding platform 2115. The ceramic insulating layer 2111 has a first side 2111a and a second side 2111b opposite to the first side 2111a. The heat-dissipating metal layer 2112 is disposed on the first side 2111a of the ceramic insulating layer 2111. The aforementioned two bonding metal layers 2113 are respectively disposed on the second side 2111b of the ceramic insulating layer 2111. The die-bonding platform 2115 is connected to one of the bonding metal layers 2113. One of the vertical transistors 2120 is connected to the die-bonding platform 2115, and the other of the vertical transistors 2120 can be connected to the aforementioned two bonding metal layers 2113.

Furthermore, the insulating metal circuit board 2050 includes a ceramic layer 2051, a plurality of first conductive metal pads 2052, a plurality of second conductive metal pads 2054 and a supporting metal element 2055. The ceramic layer 2051 has a first side 2051a and a second side 2051b opposite to the first side 2051a. The first conductive metal pads 2052 and the supporting metal element 2055 are disposed on the first side 2051a of the ceramic layer 2051. The second conductive metal pads 2054 are disposed on the second side 2051b of the ceramic layer 2051, and the second conductive metal pads 2054 are respectively electrically connected to the first conductive metal pads 2052 and the supporting metal element 2055.

It should be mentioned that, the aforementioned two vertical transistors 2120 are respectively electrically connected to the first conductive metal pads 2052. The first conductive metal pads 2052 can have different heights as shown in FIG. 19, and can be adjusted according to the size of different chips or different interconnection methods. It can be understood from the present embodiment that, the metal elements, the die-bonding platforms or other components described in the present disclosure are not limited to being disposed on a single substrate, and the position or the assembly method thereof can be adjusted according to the structural dimensions or requirements for circuit arrangement.

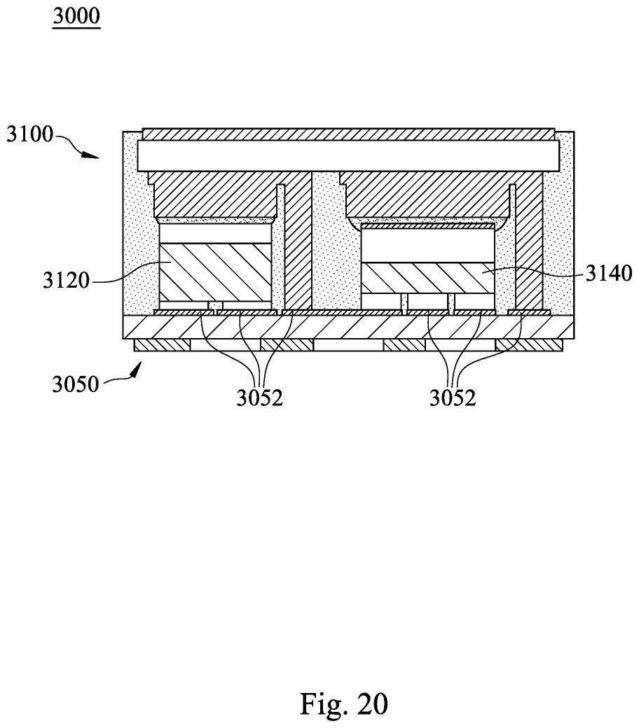

Please refer to FIG. 20. FIG. 20 is a cross-sectional schematic view of the semiconductor power package structure 3000 according to the 12th embodiment of the present disclosure. The semiconductor power package structure 3000 of the 12th embodiment is generally similar to the semiconductor power package structure 1000 of the 10th embodiment. The difference is that, the semiconductor power component 3100 of the semiconductor power package structure 3000 includes a vertical transistor 3120 and a flip chip 3140. The connection between the vertical transistor 3120 and the flip chip 3140 and other components is in the same way as the aforementioned vertical transistors 1120. Also, the vertical transistor 3120 and the flip chip 3140 can be directly interconnected through the first conductive metal pads 3052 of the insulating metal circuit board 3050 for electrical connection, and the application flexibility can be improved.

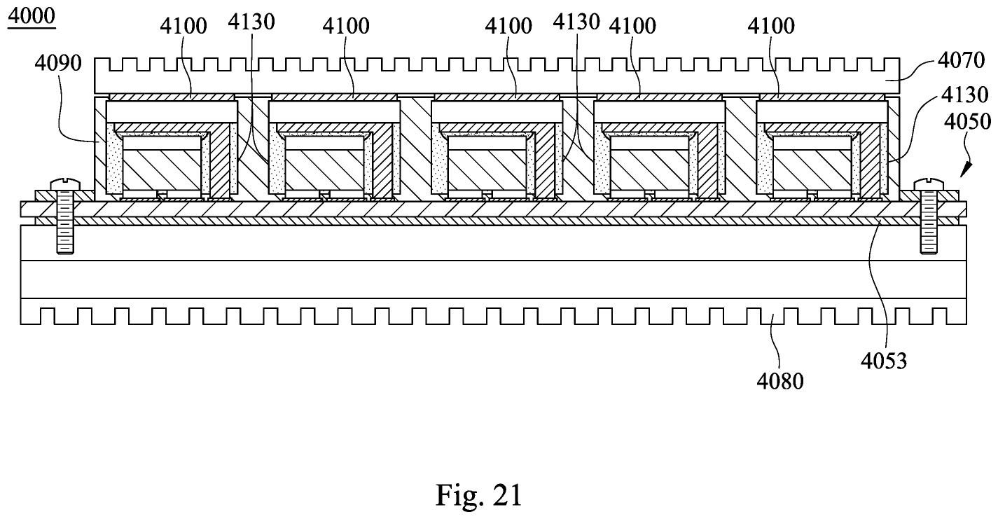

Please refer to FIG. 21. FIG. 21 is a cross-sectional schematic view of the semiconductor power package structure 4000 according to the 13th embodiment of the present disclosure. The semiconductor power package structure 4000 includes a plurality of semiconductor power components 4100, and each of the semiconductor power components 4100 is connected to the insulating metal circuit board 4050 and a heat sink 4070. The semiconductor power components 4100 are located between the insulating metal circuit board 4050 and the heat sink 4070. Moreover, the heat-conductive metal pad 4053 of the insulating metal circuit board 4050 is connected to a liquid cooling heat sink 4080, and the insulating metal circuit board 4050 is located between the semiconductor power components 4100 and the liquid cooling heat sink 4080. Therefore, heat dissipation of the semiconductor power components 4100 can be performed at both sides simultaneously. The heat dissipation efficiency can be improved, and it is favorable for quickly removing the heat under a high-power operating conditions.

It should be mentioned that, because there is no wire bonding inside the semiconductor power components 4100 and the conventional spacer is not used therein, the heights of the semiconductor power components 4100 are relatively consistent. When the semiconductor power components 4100 are connected to the heat sink 4070 and the liquid cooling heat sink 4080, the compactness therebetween can be significantly improved.

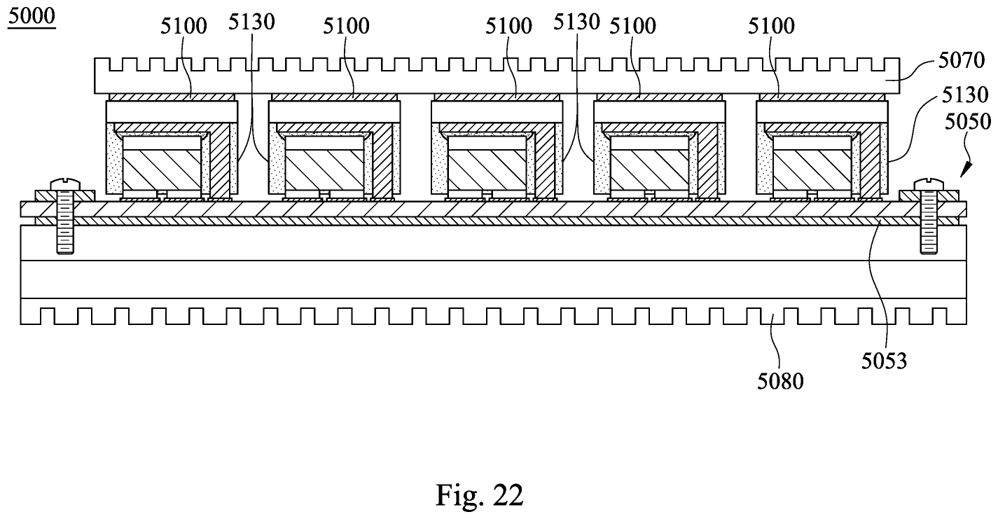

Please also refer to FIG. 22. FIG. 22 is a cross-sectional schematic view of the semiconductor power package structure 5000 according to the 14th embodiment of the present disclosure. The semiconductor power package structure 5000 of the 14th embodiment is generally similar to the semiconductor power package structure 4000 of the 13th embodiment. The difference is that, in the 13th embodiment, the filler 4130 is not in contact with the insulating metal circuit board 4050, and the semiconductor power package structure 4000 includes an additional filler 4090 surrounds the semiconductor power components 4100 and fills between the filler 4130 and the heat-conductive metal pad 4053. In the 14th embodiment, the semiconductor power package structure 5000 only includes the filler 5130. Thus, the present disclosure is not limited to the arrangement of the filler 4130, the filler 4090 and the filler 5130.

The electrical connection in the foregoing description can be achieved by forming metal bonds. The metal bonds can be formed by a metal eutectic method or a metal sintering method. A material of the metal eutectic method can be selected from the group consisting of gold, gold/tin, tin/silver/bismuth, tin/silver/bismuth/copper and tin/silver/copper. A material of the metal sintering method can be selected from the group consisting of silver metal particles, copper metal particles and silver-indium alloy particles.

In this regard, the semiconductor power component of the present disclosure is equipped with the metal element, and the metal element and the bonding metal layer are integrally formed into one. The welding steps required during packaging can be reduced, and the process yield can be improved. Also, it is favorable for using in multi-chip package structures. Furthermore, the metal element can perform a current conducting function, so there is no need for wire bonding inside the semiconductor power component. The size of the ceramic-metal composite substrate can be reduced, and it is favorable for saving the material cost.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor power component, comprising:
a ceramic-metal composite substrate, comprising:
a ceramic insulating layer having a first side and a second side opposite to the first side;
a heat-dissipating metal layer located on the first side of the ceramic insulating layer;
a bonding metal layer located on the second side of the ceramic insulating layer; and
at least one metal element connected to the bonding metal layer, wherein the bonding metal layer is located between the ceramic insulating layer and the at least one metal element;
at least one vertical transistor connected to the bonding metal layer, wherein the bonding metal layer is located between the ceramic insulating layer and the at least one vertical transistor;
wherein the at least one vertical transistor and the at least one metal element are separated from each other, and the at least one vertical transistor has a first side and a second side opposite to the first side;
wherein the at least one vertical transistor comprises a conductive pad located on the first side or the second side of the at least one vertical transistor, and the conductive pad of the at least one vertical transistor is electrically connected to the bonding metal layer; and
a filler covering the bonding metal layer and a side of the at least one metal element and a side of the at least one vertical transistor;
wherein the at least one metal element and the bonding metal layer are integrally formed into one;
wherein an end of the conductive pad and an end of the at least one metal element are protruding from the filler.

2. The semiconductor power component of claim 1, wherein the ceramic-metal composite substrate further comprises:
a die-bonding platform connected to the bonding metal layer, wherein the vertical transistor is disposed on the die-bonding platform and electrically connected to the die-bonding platform, and the die-bonding platform is located between the bonding metal layer and the vertical transistor;
wherein the die-bonding platform and the bonding metal layer are integrally formed into one.

3. The semiconductor power component of claim 1, wherein the at least one metal element partially surrounds the vertical transistor in a horizontal direction.

4. The semiconductor power component of claim 1, wherein the filler covers the ceramic insulating layer and covers at least a portion of a side of the heat-dissipating metal layer, and does not cover a surface of the heat-dissipating metal layer away from the ceramic insulating layer.

5. A semiconductor power package structure, comprising:
at least one semiconductor power component of claim 1; and
a insulating metal circuit board connected to the at least one semiconductor power component, wherein the at least one vertical transistor and the at least one metal element are located between the ceramic insulating layer and the insulating metal circuit board, and the insulating metal circuit board comprises:
a ceramic layer having a first side and a second side opposite to the first side;
a plurality of first conductive metal pads located on the first side of the ceramic layer, wherein the plurality of first conductive metal pads are electrically connected to the conductive pad of the at least one vertical transistor; and
at least one heat-conductive metal pad located on the second side of the ceramic layer.

6. The semiconductor power package structure of claim 5, wherein the insulating metal circuit board further comprises a plurality of second conductive metal pads located on the second side of the ceramic layer, and the plurality of second conductive metal pads are respectively electrically connected to the plurality of first conductive metal pads.

7. The semiconductor power package structure of claim 5, further comprising a plurality of metal conductors, wherein the plurality of metal conductors are electrically connected to the plurality of first conductive metal pads.

8. The semiconductor power package structure of claim 5, further comprising an additional filler disposed between the filler and the insulating metal circuit board.

9. A semiconductor power component, comprising:
a ceramic-metal composite substrate, comprising:
a ceramic insulating layer having a first side and a second side opposite to the first side;
a heat-dissipating metal layer located on the first side of the ceramic insulating layer;
a bonding metal layer located on the second side of the ceramic insulating layer; and
at least one metal element connected to the bonding metal layer, wherein the bonding metal layer is located between the ceramic insulating layer and the at least one metal element;
at least one flip chip connected to the bonding metal layer, wherein the at least one flip chip and the at least one metal element are separated from each other, and the at least one flip chip comprises:
a heterogeneous substrate connected to the bonding metal layer, wherein the bonding metal layer is located between the ceramic insulating layer and the heterogeneous substrate;
a semiconductor structure layer disposed on the heterogeneous substrate; and
a plurality of conductive pads disposed on the semiconductor structure layer and electrically connected to the semiconductor structure layer, wherein the semiconductor structure layer is located between the heterogeneous substrate and the plurality of conductive pads; and
a filler covering the bonding metal layer and a side of the at least one metal element and a side of the at least one flip chip;
wherein the at least one metal element and the bonding metal layer are integrally formed into one;
wherein an end of each of the plurality of conductive pads and an end of the at least one metal element are protruding from the filler.

10. The semiconductor power component of claim 9, wherein the ceramic-metal composite substrate further comprises:
a die-bonding platform connected to the bonding metal layer, wherein the at least one flip chip is disposed on the die-bonding platform, and the die-bonding platform is located between the bonding metal layer and the at least one flip chip;
wherein the die-bonding platform and the bonding metal layer are integrally formed into one.

11. The semiconductor power component of claim 9, wherein the at least one metal element partially surrounds the at least one flip chip in a horizontal direction.

12. The semiconductor power component of claim 9, wherein the filler covers the ceramic insulating layer and covers at least a portion of a side of the heat-dissipating metal layer, and does not cover a surface of the heat-dissipating metal layer away from the ceramic insulating layer.

13. A semiconductor power package structure, comprising:
at least one semiconductor power component of claim 9; and
a insulating metal circuit board connected to the at least one semiconductor power component, wherein the at least one flip chip and the at least one metal element are located between the ceramic insulating layer and the insulating metal circuit board, and the insulating metal circuit board comprises:
a ceramic layer having a first side and a second side opposite to the first side;
a plurality of first conductive metal pads located on the first side of the ceramic layer, wherein the plurality of first conductive metal pads are respectively electrically connected to the plurality of conductive pads; and
at least one heat-conductive metal pad located on the second side of the ceramic layer.

14. The semiconductor power package structure of claim 13, wherein the insulating metal circuit board further comprises a plurality of second conductive metal pads located on the second side of the ceramic layer, and the plurality of second conductive metal pads are respectively electrically connected to the plurality of first conductive metal pads.

15. The semiconductor power package structure of claim 13, further comprising an additional filler disposed between the filler and the insulating metal circuit board.

16. The semiconductor power package structure of claim 13, further comprising a plurality of metal conductors, wherein the plurality of metal conductors are electrically connected to the plurality of first conductive metal pads.

17. A semiconductor power component, comprising:
a ceramic-metal composite substrate, comprising:
a ceramic insulating layer having a first side and a second side opposite to the first side;
a heat-dissipating metal layer located on the first side of the ceramic insulating layer;
two bonding metal layers respectively located on the second side of the ceramic insulating layer; and
two metal elements respectively connected to the two bonding metal layers, wherein each of the two bonding metal layers is located between the ceramic insulating layer and the corresponding metal element;
a vertical transistor connected to one of the two bonding metal layers, wherein the one of the two bonding metal layers is located between the ceramic insulating layer and the vertical transistor, the vertical transistor and the metal element connected to the one of the two bonding metal layers are separated from each other, the vertical transistor has a first side and a second side opposite to the first side, the vertical transistor comprises a conductive pad, the conductive pad is disposed on the first side or the second side of the vertical transistor, and the conductive pad of the vertical transistor is electrically connected to the one of the two bonding metal layers;
a flip chip connected to the other one of the two bonding metal layers and separated from the metal element connected to the other one of the two bonding metal layers, wherein the flip chip comprises:
a heterogeneous substrate connected to the other one of the two bonding metal layers, wherein the other one of the two bonding metal layers is located between the ceramic insulating layer and the heterogeneous substrate;
a semiconductor structure layer located on the heterogeneous substrate; and
a plurality of conductive pads located on the semiconductor structure layer and electrically connected to the semiconductor structure layer, wherein the semiconductor structure layer is located between the heterogeneous substrate and the plurality of conductive pads; and
a filler covering the two bonding metal layers and sides of the two metal elements, a side of the vertical transistor and a side of the flip chip;
wherein each of the two metal elements and the corresponding bonding metal layer are integrally formed into one;
wherein an end of the conductive pad of the vertical transistor, an end of each of the plurality of conductive pads of the flip chip and an end of each of the two metal elements are protruding from the filler.

18. The semiconductor power component of claim 17, wherein the ceramic-metal composite substrate further comprises:
two die-bonding platforms respectively connected to the two bonding metal layers, wherein the vertical transistor is disposed on one of the two die-bonding platforms and electrically connected to the one of the two die-bonding platforms, the flip chip is disposed on the other one of the two die-bonding platforms, and each of the two die-bonding platforms is located between the corresponding bonding metal layer and the vertical transistor or the flip chip;
wherein each of the two die-bonding platforms and the corresponding bonding metal layer are integrally formed into one.

19. A semiconductor power package structure, comprising:
the semiconductor power component of claim 17; and
a insulating metal circuit board connected to the semiconductor power component, wherein the vertical transistor, the flip chip, and the two metal elements are located between the ceramic insulating layer and the insulating metal circuit board, and insulating metal circuit board comprises:
a ceramic layer having a first side and a second side opposite to the first side;
a plurality of first conductive metal pads located on the first side of the ceramic layer, wherein the plurality of first conductive metal pads are respectively electrically connected to the conductive pad of the vertical transistor and the plurality of conductive pads of the flip chip; and
at least one heat-conductive metal pad located on the second side of the ceramic layer.

20. The semiconductor power package structure of claim 19, wherein the insulating metal circuit board further comprises a plurality of second conductive metal pads located on the second side of the ceramic layer, and the plurality of second conductive metal pads are respectively electrically connected to the plurality of first conductive metal pads.

21. The semiconductor power package structure of claim 19, further comprising an additional filler disposed between the filler and the insulating metal circuit board.
